(19) United States
(12) Patent Application Publication
(10) Pub. No.: US 2012/0313688 A1
(43) Pub. Date: Dec. 13, 2012

(54) Nonvolatile Multiplexer Circuit

(76) Inventors: Alexander M. Shukh, Savage, MN (US); Tom A. Agan, Maple Grove, MN (US)

(21) Appl. No.: 13/487,241

(22) Filed: Jun. 3, 2012

Related U.S. Application Data
(60) Provisional application No. 61/494,936, filed on Jun. 9, 2011.

(51) Int. Cl. H03K 17/24

(52) U.S. Cl. 327/407

(57) ABSTRACT

A nonvolatile multiplexer circuit comprising an electric circuitry for selecting an output signal from a plurality of input signals based on select signals, the electric circuitry comprises at least one input terminal, at least one select terminal, and at least one output terminal; a high voltage source and low voltage source electrically coupled to a first and second source terminal, respectively of the electrical circuitry; at least one nonvolatile memory element comprising two stable logic states and electrically coupled to the output terminal at its first end and to an intermediate voltage source at its second end, wherein a logic state of the nonvolatile memory element is controlled by a bidirectional electrical current running through the memory element, and wherein an electrical potential of the intermediate voltage source is lower than that of the high voltage source but higher than that of the low voltage source.

### CROSS-REFERENCE TO RELATED APPLICATIONS

This application claims the benefit of provisional patent application No. 61/494,936 filed on Jun. 9, 2011 by the present inventors.

### FEDERALLY SPONSORED RESEARCH

Not Applicable

### SEQUENCE LISTING OR PROGRAM

Not Applicable

### RELEVANT PRIOR ART

U.S. Pat. No. 7,768,315, Aug. 3, 20120—Cheng at al.
U.S. Pat. No. 6,194,950, Feb. 27, 2001—Kibar et al.
U.S. Patent Application Publication No. US 2012/0105105, May 3, 2012—Shukh
Weste N. H. E., Harris D. M., CMOS VLSI Design: A Circuits and Systems Perspective, Fourth Edition, Addison—Wesley, 2011.

### BACKGROUND

A multiplexer is a semiconductor logic device that selects between two or more input signals to be transferred to an output. The conventional multiplexer has at least two inputs, at least one output and at least one control (or selection) terminal. Each of the inputs is associated with a separate and distinct path through the multiplexer. The multiplexer chooses the output from among several inputs based on a select signal.

FIG. 1 shows a block-level circuit diagram of the conventional non-inverting 2:1 multiplexer 10 having two inputs D0 and D1, one output Y, and selection S (a complementary S* not shown) terminals. A logic circuit 11 of the multiplexer 10 can have a different design implementation such as transmission gates, tristate inverters, and others. One source terminal of the multiplexer circuit 11 is connected to a high voltage source V_{DD}. Another source terminal of the circuit 11 is electrically coupled to a low voltage source V_{SS} or to the grounding source terminal GRD, where V_{DD}>V_{SS} (or GRD).

The multiplexer 10 chooses D0 signal when the select signal S=0 and the signal D1, when the select signal S=1. Hence, a logic function of the multiplexer 10 is:

Y=S*·D0+S·D1, (1)

where S* is a negation (or a complement) of S.

A truth table of the non-inverting 2-input multiplexer 10 is given in the Table 1.

The conventional multiplexers are mostly built using a complimentary metal-oxide-semiconductor (CMOS) technology employing p-type and n-type of metal-oxide-semiconductor field effect transistors (MOSFETs) to perform logic functions. The CMOS-based multiplexers have a leakage power that tends to increase with a reduction of their dimensions. The conventional multiplexers are volatile. They can lose their logic states when the power is off.

TABLE 1
Truth table of the 2:1 multiplexer

| S/S* | D1 | D0 | Y |
|---|---|---|---|
| 0/1 | X | 0 | 0 |
| 0/1 | X | 1 | 1 |
| 1/0 | 0 | X | 0 |
| 1/0 | 1 | X | 1 |

A CMOS inverter is one of key elements of the multiplexers. FIG. 2 shows a nonvolatile CMOS inverter 20 according to a prior art. The inverter 20 includes a p-type MOS (pMOS) transistor 2P1, an n-type MOS (nMOS) transistor 2N1, and a nonvolatile magnetoresitive (MR) memory element (or magnetic tunnel junction (MTJ)) 2J1. Gates of the pMOS transistor 2P1 and the nMOS transistor 2N1 are connected in common to serve as an input terminal IN. Drains of the transistors 2P1 and 2N1 also connected in common serve as an output terminal OUT. Sources of the pMOS transistor 2P1 and the nMOS transistor 2N1 are connected to voltage sources V_{DD} and V_{SS}, respectively. The nonvolatile memory element 2J1 is connected to the output terminal OUT of the inverter 20 at its first end and to a memory (or intermediate) voltage source V_{M} at its second end, where V_{DD}>V_{M}>V_{SS}. The source terminal of the nMOS transistor 2N1 can be connected to a grounding source GRD (V_{DD}>V_{M}>GRD). Moreover, the MTJ element 2J1 can also be connected to the grounding source GRD when the source terminal of to nMOS transistor 2N1 is electrically coupled to the low voltage source V_{SS}. In this case the following correlation between electric potentials of the voltage sources can be observed: V_{DD}>GRD>V_{SS}.

The MR element 2J1 can comprise at least a free (or storage) layer 22 with a reversible magnetization direction (shown by a dashed arrow), a pinned (or reference) layer 24 with a fixed magnetization direction (shown by a solid arrow), and a nonmagnetic insulating tunnel barrier layer 26 sandwiched in-between. Resistance of the memory element 2J1 depends on a mutual orientation of the magnetization directions in the free 22 and pinned 24 layers. The resistance has a highest value when the magnetization directions are antiparallel to each other, and the lowest value when they are parallel. Hence the magnetization direction of the free layer 22 can have two stable logic states. It can be controlled by a direction of a spin-polarized current I_{S} running through the element 2J1 in a direction perpendicular to layers surface (or plane). The direction of the current I_{S} and hence the magnetization direction of the free layer 22 depends on the polarity of the input signal at the gates of the transistors 2P1 and 2N1.

When an input signal IN=1 (logic “1”) is applied to the common gate terminal of the transistors 2P1 and 2N1, the pMOS transistor 2P1 is “Off” but the nMOS transistor 2N1 is “On”. The spin-polarized current I_{S} is running in the direction from the memory source V_{M} to the low voltage source V_{SS}. The current I_{S} of this direction can force the magnetization direction of the free layer 22 in parallel to the magnetization direction of the pinned layer 24, which corresponds to a logic “0”. When the input signal is changed to IN=0 (a logic “0”), the pMOS transistor 2P1 turns “On” but the nMOS transistor 2N1 is “Off”. The spin-polarizing current I_{S} is running in the opposite direction from the high voltage source V_{DD} to the memory source V_{M}. As a result, the magnetization direction of the free layer 22 can be forced in antiparallel to the magnetization direction of the pinned layer 24. This mutual orientation of the magnetizations corresponds to a high resistance state or to logic “1”. Hence, the logic value of the memory element 2J1 corresponds to a logic value at the output terminal of the conventional volatile CMOS inverter. The memory element 2J1 can provide a nonvolatile storage of the logic state of the inverter 20. The data may not be lost when the power is off.

The conventional multiplexers are volatile. They can lose their data when the power is off. This obstacle leads to a significant reboot time of logic devices using the volatile multiplexers, an increased chip size due to necessity to use an embedded block of a nonvolatile memory, longer interconnects, etc. Accordingly, it is desirable to have a nonvolatile multiplexer design.

### SUMMARY

Disclosed herein is a nonvolatile multiplexer circuit comprising an electric circuitry for selecting an output signal from a plurality of input signals based on select signals, the electric circuitry comprises at least one input terminal, at least one select terminal, and at least one output terminal; and at least one nonvolatile memory element comprising two stable logic states and eclectically coupled to the output terminal at its first end and to an intermediate voltage source at its second end, wherein a logic state of the nonvolatile memory element is controlled by a bidirectional current running through the memory element between the first and second ends.

Also disclosed is a nonvolatile multiplexer circuit comprising: an electric circuitry for selecting an output signal from a plurality of input signals based on select signals, the electric circuitry comprises a plurality of data input terminals, a plurality of select terminals, and at least one output terminal; a high voltage source electrically coupled to a first source terminal of the electrical circuitry; a low voltage source electrically coupled to a second source terminal of the electrical circuitry; at least one nonvolatile memory element comprising two stable logic states and electrically coupled to the output terminal at its first end and to an intermediate voltage source at its second end, wherein a logic state of the nonvolatile memory element is controlled by a bidirectional electrical current running through the memory element between its first and second ends, and wherein an electrical potential of the intermediate voltage source is lower than that of the high voltage source but higher than that of the low voltage source.

### BRIEF DESCRIPTION OF THE DRAWINGS

FIG. 1 is a block-level circuit diagram of a conventional non-inverting 2:1 multiplexer according to a prior art.

FIG. 2 is a transistor-level circuit diagram of a nonvolatile CMOS inverter according to a prior art.

FIG. 3 is a transistor-level circuit diagram of a nonvolatile inverting compound gate 2:1 multiplexer according to a first embodiment of the present disclosure.

FIG. 4 is a transistor-level circuit diagram of a nonvolatile inverting multiplexer according to a second embodiment of the present disclosure.

FIG. 5 is a transistor-level circuit diagram of a nonvolatile non-inverting transmission gate multiplexer according a third embodiment of the present disclosure.

FIG. 6 is a gate-level circuit diagram of a nonvolatile multiplexer according to a fourth embodiment of the present disclosure.

FIG. 7 is a block-level circuit diagram of a nonvolatile non-inverting multiplexer according to the present disclosure.

FIG. 8 is a block-level circuit diagram of a nonvolatile inverting multiplexer according to the present disclosure.

FIG. 9 is a block-level circuit diagram of a nonvolatile 4:1 multiplexer constructed according to a technical idea of the present disclosure.

### DETAILED DESCRIPTION

Embodiments of the present disclosure will be explained below with reference to the accompanying drawings. Note that in the following explanation the same reference numerals denote constituent elements having almost the same functions and arrangements, and a repetitive explanation will be made only when necessary.

Note also that each embodiment to be presented below merely discloses a device for embodying the technical idea of the present disclosure. A numerical order of the embodiments can be any. Therefore, the technical idea of the present disclosure does not limit the materials, shapes, structures, arrangements, and the like of constituent parts to those described below. The technical idea of the present disclosure can be variously changed within the scope of the appended claims.

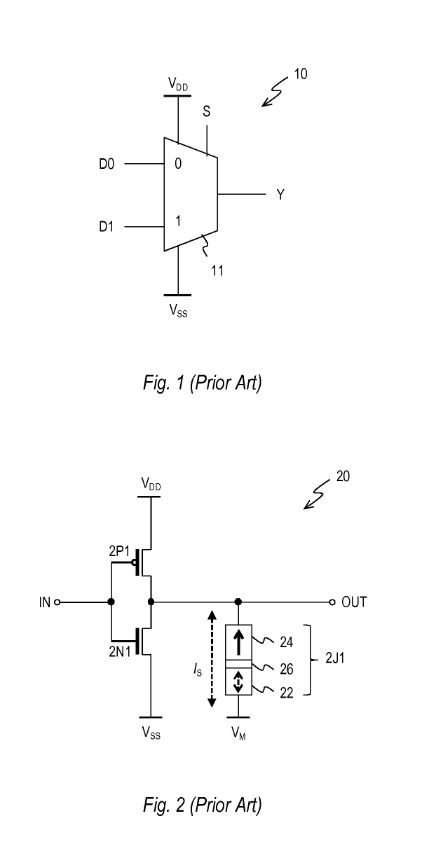

Refining now to the drawings, FIG. 2 illustrates a prior art. Specifically, the figure shows a magnetoresistive (MR) element (or magnetic tunnel junction (MTJ)) having a multilayer structure with ferromagnetic free and pinned layers having a perpendicular anisotropy. The MR element 2J1 shown in FIG. 2 for illustrative purpose comprises only the free 22 and pinned 24 ferromagnetic layers separated by a tunnel barrier layer 26. Note that additional layers can also be included in the structure of the MR element 2J1. The ferromagnetic layers 22 and 24 may also have an in-plane direction of the magnetization without departing from a scope of the present disclosure. The direction of the magnetization in the magnetic layers 22 and 24 are shown by dashed and solid arrows, respectively. The MR element 2J1 can store binary data by using steady logic states determined by a mutual orientation of the magnetizations in the free 22 and pinned 24 ferromagnetic layers separated by a tunnel barrier layer 26. The logic state “0” or “1” of the MR element 2J1 can be changed by a spin-polarized current I_{S} running through the element in the direction perpendicular to layers surface (or substrate).

The MR element herein mentioned in this specification and in the scope of claims is a general term of a tunneling magnetoresistance element using a nonmagnetic insulator or semiconductor as the tunnel barrier layer.

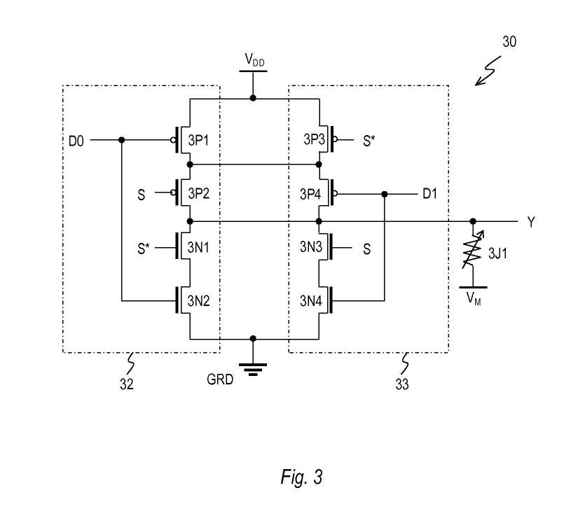

FIG. 3 shows a transistor-level circuit diagram of a nonvolatile 2-input multiplexer 30 according to a first embodiment of the present disclosure. The multiplexer 30 represents a compound gate restoring inverting design with two inputs D0 and D1, an output Y, and a select signal S. The multiplexer 30 comprises two tristate inverters 32 and 33, and a nonvolatile MR memory element 3J1. The tristate inverter 32 comprises two pMOS transistors 3P1 and 3P2, and two nMOS transistors 3N1 and 3N2 connected in series. Respectively, the tristate inverter 33 comprises connected in series pMOS transistors 3P3 and 3P4, and nMOS transistors 3N3 and 3N4. Gates of the transistors 3P1 and 3N2 are connected in common to serve as an input terminal for the signal D0. Accordingly gates of the transistors 3P4 and 3N4 connected in common form an input terminal for the signal D1. The selection signal S and its negation (or its complement) S* is applied to the gates of the transistors 3P2 and 3N3, and transistors 3N1 and 3P3, respectively. The output terminal Y is composed by drains of the transistors 3P2, 3N1, 3P4 and 3N3 connected in common. Source terminals of the pMOS transistors 3P1 and 3P3 are connected to the high voltage source V_{DD}. Source terminals of the nMOS transistors 3N2 and 3N4 are connected to the grounding voltage source GRD. The memory element 3J1 is connected to the output terminal Y at its first end and to the memory voltage source V_{M} at its second end, where V_{DD}>V_{M}>GRD. The MR element 3J1 can provide a nonvolatile storage of the output signal Y according to principals described above for the nonvolatile inverter 20 (FIG. 2). Note that the memory element 3J1 can be connected to the grounding source GRD at its second end when the source terminals of the nMOS transistors 3N2 and 3N4 are connected to the low voltage source V_{SS}, where V_{DD}>GRD>V_{SS}.

When the following combination of the signals is applied to the multiplexer 30 (D0=0, S=0, S*=1, and D1=0), the transistors 3P1 and 3P2 are “On” but the transistors 3N1-3N4, 3P3, and 3P4 are “Off”. The voltage V_{DD} is applied to the output terminal Y. A spin-polarized current I_{S} can occur in the MR element 3J1 running in the direction from the V_{DD} through the transistors 3P1 and 3P2, and the MR element 3J1 to the voltage source V_{M} (V_{DD}>V_{M}). At this direction of the spin-polarized current I_{S} the MR element 3J1 having a multilayer structure similar to the memory element 2J1 (FIG. 2) can be switched into a high resistance state (logic “1”).

Changing the input signal D0 from “0” to “1” (D0=1) when other signals are remaining unchanged (S=0, S*=1, and D1=0) can turn the transistors 3N1 and 3N2 “On”. The spin-polarized current I_{S} can occur in the circuit composed by the memory source V_{M}, MR element 3J1, the transistors 3N1, 3N2, and the grounding terminal GRD. The current I_{S} is running from the source V_{M} to the grounding source GRD (V_{M}>GRD). This direction of the spin-polarized current I_{S} can switch the MR element 3J1 having the multilyaer structure of the memory element 2J1 (FIG. 2) into the low resistance state (logic “0”).

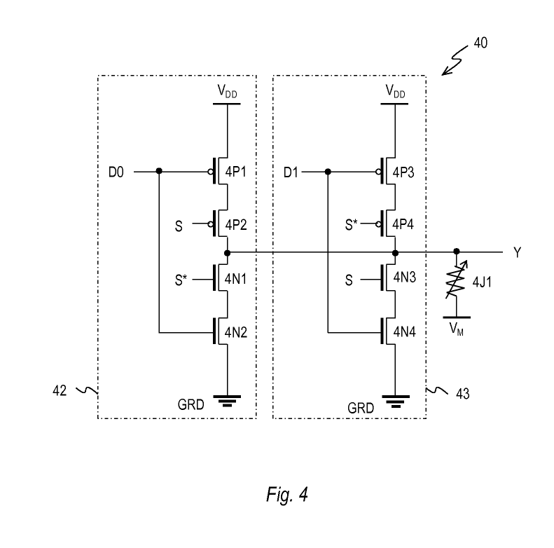

FIG. 4 shows a second embodiment of a nonvolatile inverting multiplexer 40 according to the present disclosure. The multiplexer 40 comprises two tristate inverters 42 and 43 having a common output Y, and an MR memory element 4J1. First tristate inverter 42 comprises two pMOS transistors 4P1 and 4P2, and two nMOS transistors 4N1 and 4N2 connected in series. A second tristate inverter 43 comprises transistors 4P3, 4P4, 4N3, and 4N4 also connected in series. Drains of the transistors 4P2 and 4N1 are connected in common to form an output terminal of the inverter 42. Connected in common gates of the transistors 4P1 and 4N2 compose an input terminal of the inverter 42 to where an input signal D0 is applied. Selection signals S and S* are applied to a gate of the transistors 4P2 and 4N1, respectively. Source terminals of the transistors 4P1 and 4N2 are connected to a high voltage source V_{DD} and to a grounding source GRD, respectively. Input signal D1 is applied to a common input terminal of the inverter 43 composed by gates of the transistors 4P3 and 4N4. Drains of the transistors 4P4 and 4N3 connected in common serve as an output terminal of the inverter 43. The MR memory element 4J1 is electrically coupled to the both output terminals of the inverters 42 and 43 at its first end and to a memory voltage source V_{M} at its second end, where V_{DD}>V_{M}>GRD. The source terminal of the nMOS transistors 4N2 and 4N4 can be connected to a voltage source V_{SS} when the memory element 4J1 is connected to the grounding source GRD, where V_{DD}>GRD>V_{SS}. The MR element 4J1 can provide a nonvolatile storage of the output signal Y.

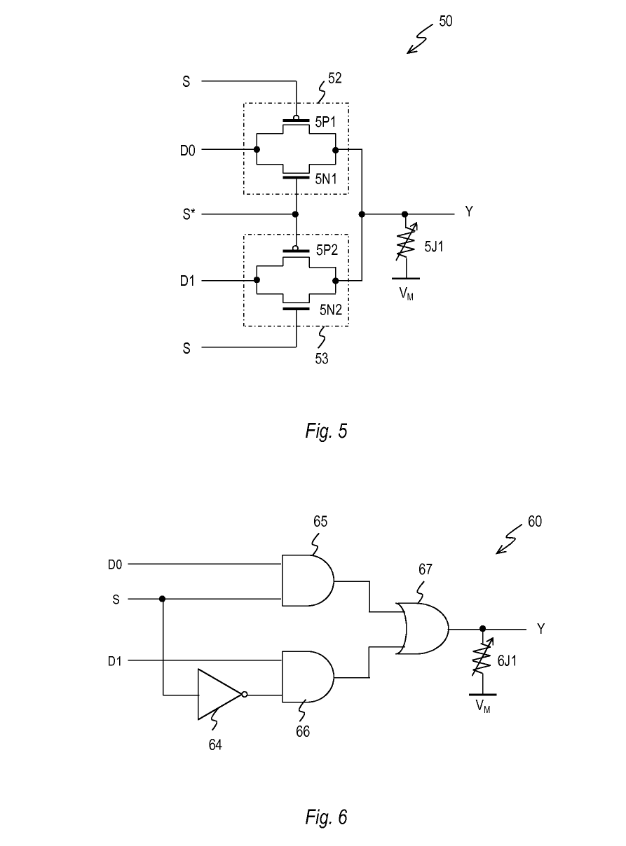

FIG. 5 shows a transistor-level circuit diagram of a nonvolatile non-inverting multiplexer 50 according to a third embodiment of the present disclosure. The multiplexer 50 comprises two transmission gates 52 and 53, and a MR memory element 5J1 that can provide a nonvolatile storage of the output signal Y. The transmission gates 52 and 53 make the multiplexer 50 non-restoring. The transmission gate 52 comprises a pMOS transistor 5P1 and nMOS transistor 5N1 connected in parallel. The input terminal D0 of the gate 52 is composed by source terminals of the transistors 5P1 and 5N1 connected in common. Respectively, the output terminal Y of the transmission gate 52 is made of the drain terminals of the transistors 5P1 and 5N1 also connected in common. Selection signals S and S* can be applied to the gate terminals of the transistors 5P1 and 5N1, respectively. The other transmission gate 53 includes a pMOS transistor 5P2 and nMOS transistor 5N2 also connected in parallel. The transmission gate 53 comprises an input terminal D1 and the output terminal that is connected in common with the output terminal of the transmission gate 52. The MTJ memory element 5J1 is electrically coupled to the common output terminal Y of the transmission gates 52 and 53 at its first end and to a memory voltage source V_{M} at its second end. The select signal S and its complement S* can enable simultaneously one of the two transmission gates 52 or 53 at any given time when both the pMOS and nMOS transistors of the gate are “On”. A magnitude of the input signals D0 and D1 is substantially similar to value of V_{DD} or V_{SS} when logic “1” or logic “0”, respectively is applied to the input terminals, where V_{DD}>V_{M}>V_{SS}. The non-restoring multiplexer 50 can be converted into a restoring one, for example by adding the inverter 20 (FIG. 2).

FIG. 6 shows a logic gate-level circuit diagram of a nonvolatile multiplexer 60 according to a fourth embodiment of the present disclosure. The multiplexer 60 comprises, an inverter 64, two AND logic gates 65 and 66, an OR gate 67, and MR memory element 6J1. The memory element 6J1 is electrically coupled to an output terminal of the OR gate 67 at its first end and to a memory voltage source V_{M} at its second end. The memory element 6J1 can provide a nonvolatile storage of an output signal Y. Number of MTJ memory elements can vary, for example additional MR elements can be connected to the output terminals of the logic gates 65 and 66. Another placements and number of the MR elements can be used as well.

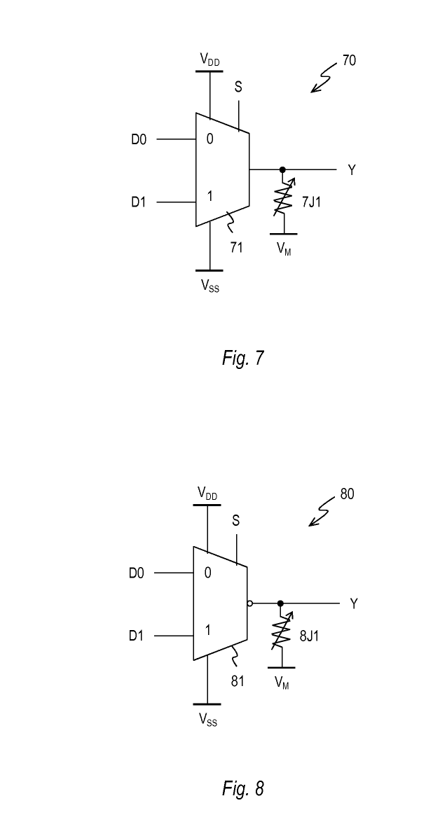

FIG. 7 shows a block-level circuit diagram of a nonvolatile non-inverting multiplexer 70 according to the present disclosure. Respectively, FIG. 8 shows a block-level circuit diagram of the nonvolatile inverting multiplexer 80. The non-volatility of the output signal of both inverters 70 and 80 can be provided by the MR elements 7J1 and 8J1, respectively. Each of the MR elements are connected to the output terminal of the inverter at its first end and to the memory voltage source V_{M} at its second end, where V_{DD}>V_{M}>V_{SS}.

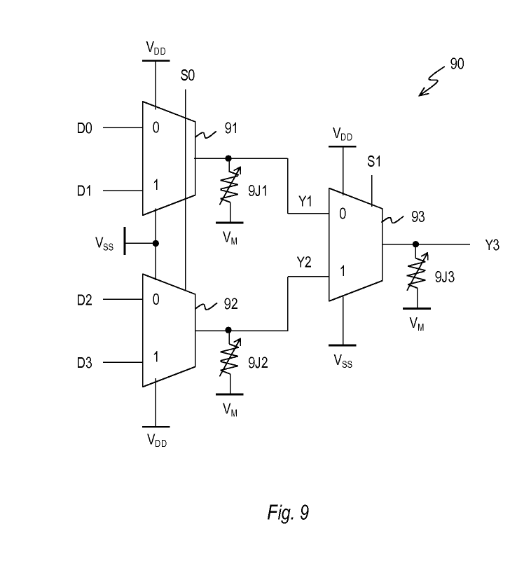

FIG. 9 shows a block-level circuit diagram of 4:1 nonvolatile multiplexer 90 constructed according to the technical idea of the present disclosure. The multiplexer 90 can comprise three 2:1 multiplexers 91-93 and three nonvolatile memory elements 9J1-9J3 coupled to the output terminals of the appropriate multiplexers. The multiplexer 90 can have four input terminals D0-D3 and two select signal terminals S0 and S1. The select signal S0 (and S0*) can be applied simultaneously to the multiplexers 91 and 92 to provide a selection between the input signals D0 or D1 and D2 or D3. The output signals Y1 and Y2 can serve as input signals of the multiplexer 93. The output signal Y3 can be selected from the signals Y1 and Y2 by an application of the select signal S1 to the multiplexer 93.

The nonvolatile storage of the logic values Y1, Y2, and Y3 can be provided by the MR elements 9J1, 9J2, and 9J3, respectively. Number of the MR elements of the multiplexer 90 can vary, for example the memory elements 9J1 and 9J2 can be omitted.

The multiplexer circuits shown in FIGS. 3-9 employ the MR elements (or MTJs) as nonvolatile memory elements. Note that the MR elements can be replaced by another nonvolatile memory elements such as a phase change memory element, resistive memory element and others without departing from the scope of the present disclosure.

The disclosed nonvolatile multiplexer circuits comprise the nonvolatile memory elements disposed above a CMOS logic circuitry formed on a wafer (or substrate). The embedded nonvolatile memory elements can have a marginal impact on a design and manufacturing process of the conventional volatile CMOS-based multiplexer circuits.

While the specification of this disclosure contains many specifics, these should not be construed as limitations on the scope of the disclosure or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

It is understood that the above embodiments are intended to be illustrative, and not restrictive. Many other embodiments will be apparent to those of skill in the art upon reviewing the above description. The scope of the embodiments should be, therefore, determined with reference to the appended claims, along with the full scope of equivalents to which such claims are entitled.

While the disclosure has been described in terms of several exemplary embodiments, those skilled in the art will recognize that the disclosure can be practiced with modification within the spirit and scope of the appended claims. Specifically, one of ordinary skill in the art will understand that the drawings herein are meant to be illustrative, and the spirit and scope of the disclosure are not limited to the embodiments and aspects disclosed herein but may be modified.

What is claimed is:

1. A nonvolatile multiplexer circuit comprising:
an electric circuitry for selecting an output signal from a plurality of input signals based on select signals, the electric circuitry comprises at least one input terminal, at least one select terminal, and at least one output terminal; and
at least one nonvolatile memory element comprising two stable logic states and eclectically coupled to the output terminal at its first end and to an intermediate voltage source at its second end,
wherein a logic state of the nonvolatile memory element is controlled by a bidirectional current running through the memory element between the first and second ends.

2. The nonvolatile multiplexer circuit of claim 1, further comprising:
a high voltage source electrically coupled to a first source terminal of the electrical circuitry;
a low voltage source electrically coupled to a second source terminal of the electrical circuitry,
wherein an electrical potential of the intermediate voltage source is lower than that of the high voltage source but higher than that of the low voltage source.

3. The nonvolatile multiplexer circuit of claim 1, wherein the nonvolatile memory element is magnetoresistive element.

4. The nonvolatile multiplexer circuit of claim 3, wherein the magnetoresistive element comprises at least a free ferromagnetic layer comprising a reversible magnetization direction, a pinned ferromagnetic layer comprising a fixed magnetization direction, and a nonmagnetic insulating tunnel barrier layer disposed between the free and pinned layers.

5. The nonvolatile multiplexer circuit of claim 4, wherein the magnetization direction of the free ferromagnetic layer comprises a first logic state that is parallel to the magnetization direction of the pinned layer and a second logic state that is antiparallel to the magnetization direction of the pinned layer.

6. The nonvolatile multiplexer circuit of claim 4, wherein the magnetization directions of the free and pinned ferromagnetic layers are substantially perpendicular to a layers surface.

7. The nonvolatile multiplexer circuit of claim 4, wherein the magnetization directions of the free and pinned layers are substantially parallel to the layers surface.

8. The nonvolatile multiplexer circuit of claim 1, wherein the nonvolatile memory element comprises a phase change material which has a high resistance state when it is in an amorphous state and has a low resistance state when it is in a crystalline state.

9. A nonvolatile multiplexer circuit comprising:
an electric circuitry for selecting an output signal from a plurality of input signals based on select signals, the electric circuitry comprises a plurality of data input terminals, a plurality of select terminals, and at least one output terminal;
a high voltage source electrically coupled to a first source terminal of the electrical circuitry;
a low voltage source electrically coupled to a second source terminal of the electrical circuitry;
at least one nonvolatile memory element comprising two stable logic states and electrically coupled to the output terminal at its first end and to an intermediate voltage source at its second end,
wherein a logic state of the nonvolatile memory element is controlled by a bidirectional electrical current running through the memory element between its first and second ends, and
wherein an electrical potential of the intermediate voltage source is lower than that of the high voltage source but higher than that of the low voltage source.

10. The nonvolatile multiplexer circuit of claim 9, wherein the nonvolatile memory element is magnetoresistive element.

11. The nonvolatile multiplexer circuit of claim 10, wherein the magnetoresistive element comprises at least a free ferromagnetic layer comprising a reversible magnetization direction, a pinned ferromagnetic layer comprising a fixed magnetization direction, and a nonmagnetic insulating tunnel barrier layer disposed between the free and pinned layers.

12. The nonvolatile multiplexer circuit of claim 11, wherein the magnetization direction of the free ferromagnetic layer comprises a first logic state that is parallel to the magnetization direction of the pinned layer and a second logic state that is antiparallel to the magnetization direction of the pinned layer.

13. The nonvolatile multiplexer circuit of claim 11, wherein the magnetization directions of the free and pinned ferromagnetic layers are substantially perpendicular to a layers surface.

14. The nonvolatile multiplexer circuit of claim 11, wherein the magnetization directions of the free and pinned layers are substantially parallel to the layers surface.

15. The nonvolatile multiplexer circuit of claim 9, wherein the nonvolatile memory element comprises a phase change material which has a high resistance state when it is in an amorphous state and has a low resistance state when it is in a crystalline state.
